(19) United States
(12) Patent Application Publication
(10) Pub. No.: US 2012/0264253 A1
(43) Pub. Date: Oct. 18, 2012

(54) METHOD OF FABRICATING SOLAR CELL

(75) Inventors: Ming-Hui Chiu, New Taipei City (TW); Shih-Hsien Yang, Taichung City (TW); Yen-Cheng Hu, New Taipei City (TW); Yu-Chun Chen, New Taipei City (TW); Tsung-Pao Chen, Taichung City (TW); Kuan-Chen Wang, Pingtung County (TW); Jen-Chieh Chen, Miaoli County (TW); Zhen-Cheng Wu, Taichung City (TW)

(73) Assignee: AU OPTRONICS CORPORATION, Hsinchu (TW)

(21) Appl. No.: 13/190,498

(22) Filed: Jul. 26, 2011

(30) Foreign Application Priority Data
Apr. 15, 2011 (TW) 100113232

(51) Int. Cl. H01L 31/18

(52) U.S. Cl. 438/73; 257/E31.032

(57) ABSTRACT

A method of fabricating a solar cell is provided. A first type substrate having a first surface and a second surface is provided. A first doping process is performed on the first surface of the first type substrate by using a first dopant, so as to form a first type lightly doped layer. A second doping process is performed on a portion of the first type lightly doped layer by using a second dopant, so as to form a second type heavily doped region. A molecular weight of the second dopant is larger than a molecular weight of the first dopant, and a temperature of the first doping process is higher than a temperature of the second doping process. A first electrode is formed on the second type heavily doped region. A second electrode is formed on the second surface of the first type substrate.

### CROSS-REFERENCE TO RELATED APPLICATION

This application claims the priority benefit of Taiwan application serial no. 100113232, filed on Apr. 15, 2011. The entirety of the above-mentioned patent application is hereby incorporated by reference herein and made a part of this specification.

### BACKGROUND OF THE INVENTION

1. Field of the Invention

The invention relates to a method of fabricating a solar cell, and more particularly to a method of fabricating a solar cell having favorable efficiency.

2. Description of Related Art

A silicon-based solar cell is a commonly used solar cell in the industry. A principle of the silicon-based solar cell is to dope a semiconductor material (i.e. silicon) with different type dopants to form a p-type semiconductor layer and an n-type semiconductor layer, and then to assemble the p-type semiconductor layer and the n-type semiconductor layer together, so as to form a p-n junction. When sunlight irradiates the semiconductor material with the p-n junction, energy carried by photons can excite electrons in the semiconductor material to generate electron-hole pairs. By respectively disposing electrodes on the p-type semiconductor layer and the n-type semiconductor layer, the electrons and the holes are all influenced by a built-in potential, wherein the holes move towards an electric field, and the electrons move towards an opposite direction, such that the solar cell is constituted.

Generally, in order to improve the electrical contact between the semiconductor layer and the electrode, a heavily doped selective emitter is formed in the lightly doped semiconductor layer. As such, series resistance is reduced, and efficiency of the solar cell is increased. However, as the heavily doped selective emitter and the lightly doped semiconductor layer are usually formed by doping with identical dopants, the difference of the conductivity therebetween is not significant. Therefore, efficiency of the solar cell is difficult to improve.

### SUMMARY OF THE INVENTION

The invention is directed to a method of fabricating a solar cell, so as to form a solar cell having favorable efficiency.

A method of fabricating a solar cell is provided. A first type substrate having a first surface and a second surface is provided. A first doping process is performed on the first surface of the first type substrate by using a first dopant, so as to form a first type lightly doped layer. A second doping process is performed on a portion of the first type lightly doped layer by using a second dopant, so as to form a second type heavily doped region. A molecular weight of the second dopant is larger than a molecular weight of the first dopant, and a temperature of the first doping process is higher than a temperature of the second doping process. A first electrode is formed on the second type heavily doped region. A second electrode is formed on the second surface of the first type substrate.

Based on the above, in the method of fabricating the solar cell of the invention, the lightly doped layer is formed by using a first dopant, and the heavily doped region is formed by using a second dopant, wherein a molecular weight of the second dopant is larger than a molecular weight of the first dopant, and a temperature of the first doping process is higher than a temperature of the second doping process. As such, a heavily doped region having a shallow depth is clearly defined in the lightly doped layer, and thus a favorable ohmic contact is formed between the heavily doped region served as a selective emitter and the electrode. Therefore, the recombination rate of the electron-hole pairs in the solar cell is greatly increased and the efficiency of the solar cell is improved.

In order to make the aforementioned and other features and advantages of the invention more comprehensible, embodiments accompanying figures are described in detail below.

### BRIEF DESCRIPTION OF THE DRAWINGS

The accompanying drawings constituting a part of this specification are incorporated herein to provide a further understanding of the invention. Here, the drawings illustrate embodiments of the invention and, together with the description, serve to explain the principles of the invention.

FIG. 1A to FIG. 1F are schematic cross-sectional views illustrating a method of fabricating a solar cell according to an embodiment of the invention.

### DESCRIPTION OF EMBODIMENTS

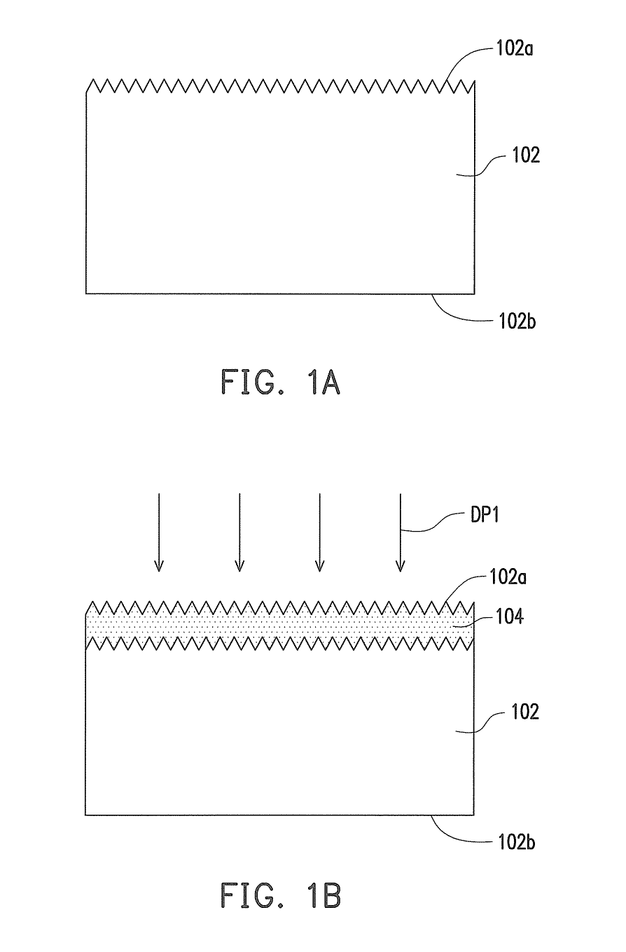

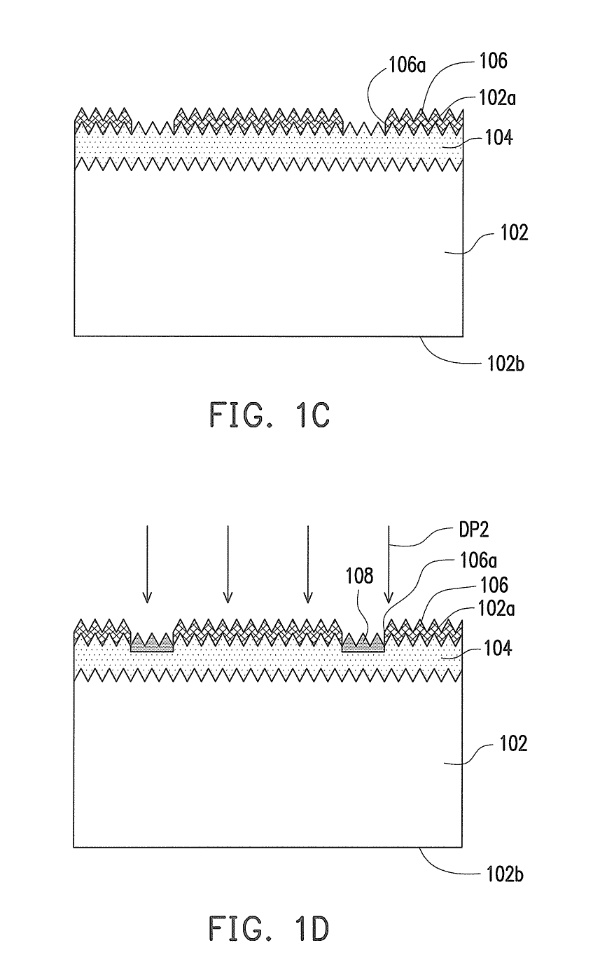

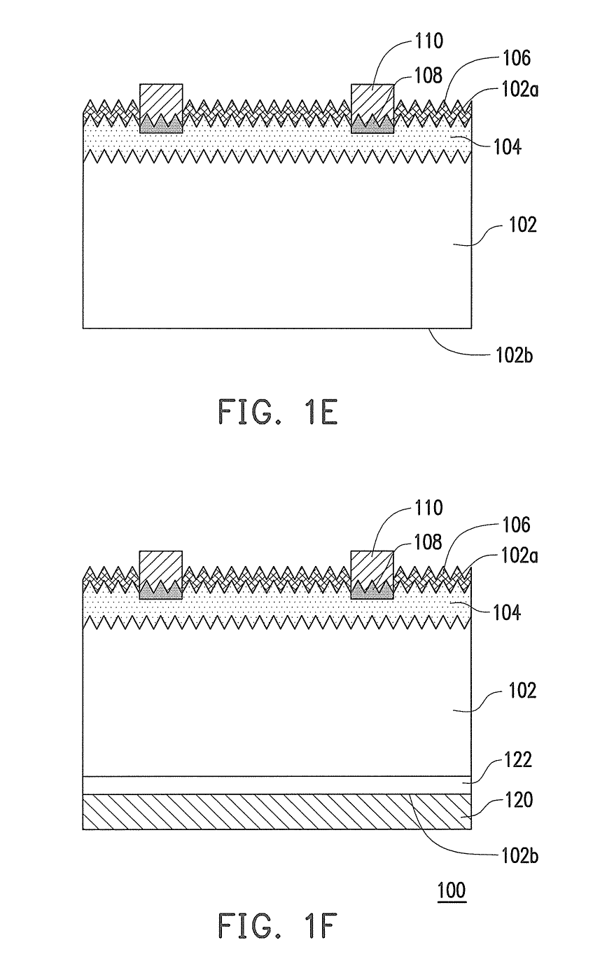

FIG. 1A to FIG. 1F are schematic cross-sectional views illustrating a method of fabricating a solar cell according to an embodiment of the invention. Reference with FIG. 1A, a first type substrate 102 having a first surface 102a and a second surface 102b is provided. In this embodiment, the first type is p-type, and the second type is n-type, for example. Conversely, in another embodiment, the first type can be n-type, and the second type can be p-type. In this embodiment, the first type substrate 102 is a semiconductor material doped with p-type dopants. The p-type dopants can be selected from Group III, such as boron ions (B), aluminum ions (Al), gallium ions (Ga) or indium ions (In). In addition, a material of the substrate 102 can be silicon, CdS, CuInGaSe₂ (CIGS), CuInSe₂ (CIS), CdTe, organic material or a multi-layered structure comprising the aforementioned materials. The silicon can include single crystal silicon, polycrystal silicon, amorphous silicon or microcrystal silicon. The first surface 102a is an upper surface, and a second surface 102b is a lower surface, for example. Particularly, in this embodiment, the first surface 102a of the first type substrate 102 is a textured surface represented as saw-toothed surface in FIG. 1A, so as to increase light absorption, for example.

Reference with FIG. 1B, then, a first doping process DP1 is performed on the first surface 102a of the first type substrate 102 by using first dopants, so as to form a first type lightly doped layer 104. In this embodiment, the first dopants are n-type dopants, and the n-type dopants can be selected from Group V, such as phosphorous ions (P), arsenic ions (As) or antimony ions (Sb). The first doping process DP1 is, for example, a thermal diffusion process or an ion implantation process. In this embodiment, the temperature of the first doping process DP1 ranges from 800° C. to 1000° C., and preferably from 800° C. to 850° C. In this embodiment, the first type lightly doped region 104 is an n-type lightly doped region, for example. The thickness of the first type lightly doped region 104 can range from 0.2 um to 0.6 um.

Reference with FIGS. 1C and 1D, next, a second doping process DP2 is performed on a portion of the first type lightly doped layer 104 by using second dopants, so as to form a second type heavily doped region 108. The molecular weight of the second dopant is larger than the molecular weight of the first dopant, and the temperature of the first doping process DP1 is higher than the temperature of the second doping process DP2.

In this embodiment, a method of forming the second type heavily doped region 108 includes the following steps. First, as shown in FIG. 1C, a mask layer 106 is formed on the first type lightly doped layer 104, and the mask layer 106 has an opening 106a exposing the portion of the first type lightly doped layer 104. In this embodiment, a material of the mask layer 106 has anti-reflective property, such as Si₃N₄, SiO₂, TiO₂, MgF₂ or the recombination thereof, for example. A thickness of the mask layer 106, for example, ranges from 70 nm to 90 nm. A method of forming the mask layer 106 is, for example, to form a mask material layer entirely covering the first type lightly doped layer 104 by plasma-enhanced chemical vapor deposition (PECVD) and then to pattern the mask material layer, so as to form the mask layer 106 having the opening or openings 106a to expose a portion of the first type lightly doped layer 104, wherein the portion mentioned above of the first type lightly doped layer 104 may be discrete top surfaces of the first type lightly doped layer 104, but not limited herein. A method of patterning the mask material layer includes an etching paste process, a laser process, a photolithography process or other methods. It is noted that, in another embodiment, the mask layer 106 can be also made of other materials without anti-reflective property.

As shown in FIG. 1D, then, by using the mask layer 106 as a mask, a second doping process DP2 is performed on a portion of the first type lightly doped layer 104 by using second dopants through the opening 106a, so as to form the second type heavily doped region 108. In this embodiment, the second dopants are n-type dopants, and the n-type dopants can be selected from Group V, such as phosphorous ions (P), arsenic ions (As) or antimony ions (Sb). Note that the molecular weight of the second dopant is larger than the molecular weight of the first dopant, for instance, the first dopants are phosphorous ions (P) while the second dopants are arsenic ions (As) or antimony ions (Sb), and the first dopants are arsenic ions (As) while the second dopants are antimony ions (Sb). In this embodiment, the second doping process DP2 is, for example, a thermal diffusion process or an ion implantation process. The temperature of the second doping process DP2, for example, ranges from 700° C. to 900° C. In this embodiment, the temperature of the first doping process DP1, for example, ranges from 800° C. to 850° C., and preferably 850° C., and the temperature of the second doping process DP2, for example, ranges from 800° C. to 850° C., and preferably from 823° C. to 825° C., wherein the temperature of the first doping process DP1 is higher than the temperature of the second doping process DP2. In this embodiment, the second type heavily doped region 108 is, for instance, a n-type heavily doped region, and a thickness of the second type heavily doped region 108, for instance, ranges from 0.1 um to 0.15 um. In this embodiment, the second type heavily doped region 108 is substantially served as a heavily doped selective emitter.

Reference with FIG. 1E, after that, a first electrode 110 is formed on the second type heavily doped region 108. A material of the first electrode 110 is, for example, silver, titanium-palladium-silver alloy, or other suitable conductive materials. A method of forming the first electrode 110 is, for example, plating, printing, metal organic chemical vapor deposition (MOCVD) or evaporation, and the invention is not limited thereto. Particularly, in this embodiment, the mask layer 106 can be remained on the first type substrate 102 as an anti-reflective layer, and therefore the first electrode 110 can be directly formed in the opening 106a by printing or other similar methods. In other words, the patterning process to the conductive layer used to form the first electrode 110 is not required. Conversely, if the material of the mask layer 106 does not have anti-reflective property, the mask layer 106 is required to be removed and an anti-reflective layer is additionally formed on the first type substrate 102. In this case, the first electrode 110 is formed on the anti-reflective layer, and particularly, the first electrode 110 is formed at positions corresponding to the second type heavily doped region 108 by adopting an etching paste method, for example.

Reference with FIG. 1F, than, a second electrode 120 is formed on the second surface 102b of the first type substrate 102. A material of the second electrode 120 is, for example, aluminum, or other suitable conductive materials. A method of forming the second electrode 120 is similar to the method of forming the first electrode 110 described above, and a detail description thereof is not repeated. Particularly, in this embodiment, in order to prevent effects generated by recombination of carriers near the back surface of the first type substrate 102, a back surface field (BSF) layer 122 is disposed between the first type substrate 102 and the second electrode 120. A method of forming the back surface field (BSF) layer 122 is, for example, a co-firing process. In this embodiment, after forming the second electrode 120, the method of fabricating a solar cell 100 is generally completed.

In this embodiment, the mask layer 106 can be remained as an anti-reflective layer in the solar cell 100 because the material of the mask layer 106 has anti-reflective property. Alternatively, in another embodiment (not shown), after formation of the second type heavily doped region 108, the mask layer 106 without anti-reflective property can be removed, an anti-reflective layer is additionally formed on the first type lightly doped layer 104, and then the first electrode 110 and the second electrode 120 are respectively formed on the second type heavily doped region 108 and the second surface 102b of the first type substrate 102. In other words, the material of the mask layer can be selected and the anti-reflective layer is alternatively formed according to actual requirements. Moreover, the second type heavily doped region 108 can be formed by other suitable methods.

In this embodiment, the lightly doped layer and the heavily doped region are formed by using different dopants. In detail, the first dopants having a smaller molecular weight are firstly used to perform the first doping process to form the lightly doped layer, and the second dopants having a larger molecular weight are then used to perform the second doping process to form the heavily doped region in the lightly doped layer. Since the molecular weight of the second dopants is larger than the molecular weight of the first dopants, and the temperature of the first doping process is higher than the temperature of the second doping process, the heavily doped region having a shallow depth is accurately formed by the lightly doped process with the second dopants. As such, the heavily doped region having a shallow depth is clearly defined in the lightly doped layer, and thus a favorable ohmic contact is formed between the heavily doped region served as a selective emitter and the electrode. Therefore, the recombination rate of the electron-hole pairs in the solar cell is greatly increased and the efficiency of the solar cell is improved. Particularly, in this embodiment, the mask layer can be remained as an anti-reflective layer in the solar cell because the material of the mask layer has anti-reflective property, and therefore the removal process to the mask layer is not required. Accordingly, the fabricating process of the solar cell is simplified and the efficiency of the solar cell is increased.

In light of the foregoing, in the method of fabricating solar cell of the invention, the lightly doped layer is formed by using first dopants, and the heavily doped region is formed by using second dopants, wherein a molecular weight of the second dopant is larger than a molecular weight of the first dopant, and a temperature of the first doping process is higher than a temperature of the second doping process. As such, the heavily doped region having a shallow depth is clearly defined in the lightly doped layer, and thus a favorable ohmic contact is formed between the heavily doped region served as a selective emitter and the electrode. Therefore, the recombination rate of the electron-hole pairs in the solar cell is greatly increased and the efficiency of the solar cell is improved. Moreover, the method of fabricating solar cell of the invention is compatible with existing processes, and thus additional processing apparatus is not required and the cost of fabricating the solar cell is not greatly increased.

Although the invention has been described with reference to the above embodiments, it will be apparent to one of the ordinary skill in the art that modifications to the described embodiment may be made without departing from the spirit of the invention. Accordingly, the scope of the invention will be defined by the attached claims not by the above detailed descriptions.

What is claimed is:

1. A method of fabricating a solar cell, comprising:
providing a first type substrate having a first surface and a second surface;
performing a first doping process by using a first dopant on the first surface of the first type substrate to form a first type lightly doped layer;
performing a second doping process by using a second dopant on a portion of the first type lightly doped layer to form a second type heavily doped region, wherein a molecular weight of the second dopant is larger than a molecular weight of the first dopant, and a temperature of the first doping process is higher than a temperature of the second doping process;
forming a first electrode on the second type heavily doped region; and
forming a second electrode on the second surface of the first type substrate.

2. The method as claimed in claim 1, wherein the first type lightly doped layer is p-type, and the second type heavily doped region is n-type.

3. The method as claimed in claim 2, wherein the first dopant comprises phosphorous ion (P).

4. The method as claimed in claim 3, wherein the second dopant comprises arsenic ion (As) or antimony ion (Sb).

5. The method as claimed in claim 2, wherein the first dopant comprises arsenic ion (As).

6. The method as claimed in claim 5, wherein the first dopant comprises antimony ion (Sb).

7. The method as claimed in claim 1, wherein the first type lightly doped layer is n-type, and the second type heavily doped region is p-type.

8. The method as claimed in claim 7, wherein the temperature of the first doping process ranges from 800° C. to 1000° C.

9. The method as claimed in claim 8, wherein the temperature of the second doping process ranges from 700° C. to 900° C.

10. The method as claimed in claim 1, wherein the temperature of the first doping process ranges from 800° C. to 1000° C.

11. The method as claimed in claim 10, wherein the temperature of the second doping process ranges from 700° C. to 900° C.

12. The method as claimed in claim 1, wherein the step of forming the second type heavily doped region comprises:
forming a mask layer on the first type lightly doped layer, wherein the mask layer has an opening exposing the portion of the first type lightly doped layer; and
performing the second doping process by using the mask layer as a doping mask on the portion of the first type lightly doped layer through the opening.

13. The method as claimed in claim 12, wherein the mask layer comprises an anti-reflective layer.

14. The method as claimed in claim 12, further comprising removing the mask layer.

15. The method as claimed in claim 1, wherein a material of the first electrode comprises silver or titanium-palladium-silver alloy.

16. The method as claimed in claim 1, wherein a material of the second electrode comprises aluminum.

17. The method as claimed in claim 1, wherein a thickness of the second type heavily doped region ranges from 0.1 μm to 0.15 μm.
